(19) United States
(12) Patent Application Publication
(10) Pub. No.: US 2025/0162303 A1
(43) Pub. Date: May 22, 2025

(54) A METHOD FOR MANUFACTURING A BARRIER LAYER FOR A PAPER OR PAPERBOARD BASED PACKAGING LAMINATE

(71) Applicant: Stora Enso OYJ, Helsinki (FI)

(72) Inventors: Isto Heiskanen, Imatra (FI); Tommi Nordström, Turku (FI); Kaj Backfolk, Lappeenranta (FI); Raino Kauppinen, Lappeenranta (FI)

(73) Assignee: Stora Enso OYJ, Helsinki (FI)

(21) Appl. No.: 18/842,939

(22) PCT Filed: Feb. 23, 2023
(86) PCT No.: PCT/IB2023/051663

§ 371 Date: Aug. 30, 2024

(30) Foreign Application Priority Data
Mar. 2, 2022 (SE) 2250283-5

(51) Int. Cl. B32B 37/24; B32B 7/12; B32B 29/06; B32B 37/00; B32B 37/06; B32B 37/10; B32B 37/26

(52) U.S. Cl. CPC B32B 37/24; B32B 7/12; B32B 29/06; B32B 37/025; B32B 37/06; B32B 37/10; B32B 2037/243; B32B 2037/268; B32B 2307/7244; B32B 2307/7246; B32B 2307/7376

(57) ABSTRACT

The present invention relates to a method for manufacturing a barrier layer for a paper or paperboard based packaging laminate. said method comprising: a) providing a barrier substrate comprising at least 50 wt % highly refined cellulose pulp (HRC) based on dry weight of the barrier substrate. said HRC having a Schopper-Riegler (SR) number above 80 as determined by standard ISO 5267-1, b) providing a transfer coating substrate comprising a vacuum coating layer and a backing layer separated by a release layer, and c) transferring the vacuum coating layer from the backing layer to the barrier substrate by a transfer coating process using an adhesive layer applied on the barrier substrate and/or the vacuum coating layer to obtain a barrier layer for a paper or paperboard based packaging laminate.

### TECHNICAL FIELD

The present disclosure relates to barrier layers for paper or paperboard based packaging materials. More specifically, the present disclosure relates to barrier layers for paper or paperboard based packaging laminates having low oxygen transmission rate (OTR) and low water vapor transmission rate (WVTR).

### BACKGROUND

Coating of paper and paperboard with plastics is often employed to combine the mechanical properties of the paper or paperboard with the barrier and sealing properties of a plastic film. Paper or paperboard provided with even a relatively small amount of a suitable plastic material can provide the properties needed to make the paper or paperboard suitable for many demanding applications, for example as liquid or food packaging board. In liquid or food packaging board, polyolefin coatings are frequently used as liquid barrier layers, heat sealing layers and adhesives. However, the recycling of such polymer coated board is difficult since it is difficult to separate the polymers from the fibers.

Also, in many cases the water vapor barrier properties of the polymer coated paper or paperboard are still insufficient unless the coating layers are thick or combinations of different polymer coating layers are used. Therefore, in order to ensure high water vapor barrier properties, the polymer coated paper or paperboard is often combined with one or more layers of aluminum foil. However, the addition of polymer and aluminum foil add significant costs and the combination of polymer coating layers and aluminum foils makes recycling of the materials more difficult. Also, due to its high carbon footprint there is a wish to replace aluminum foils in paper and paperboard based packaging materials.

Aseptic packaging for long shelf-life products such as milk and juices are usually made from liquid or food packaging board comprising a multilayer paperboard based substrate, an outermost heat-sealable polyolefin (e.g. polyethylene, PE) layer and innermost layers of polyolefin and aluminum. The aluminum foil layer, needed to provide water vapor and oxygen barrier properties, is usually incorporated between layers of polyethylene to provide the following structure: PE/paperboard/PE/aluminum/PE.

In the prior art, attempts have been made to replace the aluminum foil with more environmentally friendly and/or easier to recycle solutions, but so far with no real success. For example, microfibrillated cellulose (MFC) films and coatings have been developed, in which defibrillated cellulosic fibrils have been dispersed e.g. in water and thereafter re-organized and rebonded together to form a dense film or coating with excellent gas barrier properties. Unfortunately, the water vapor and gas barrier properties of such MFC films tend to deteriorate at high humidity.

One solution discussed in the prior art is to deposit a thin vacuum coating layer directly onto the MFC film or coating using for example chemical or physical vapor deposition techniques. The thin vacuum coating layer may for example comprise a thin layer of aluminum, Al₂O₃, AlOx, or SiOx. A problem with these deposition techniques is that the coating process takes place under vacuum, which means that the substrate needs to be degassed. For MFC films and coatings, this means that the process adds costs, but the degassing also means that the substrate is dried to a very low moisture content. This drying and the subsequent remoisturizing to ambient moisture levels changes the mechanical properties of the MFC films and coatings. The drying will not only increase the cracking tendency and post-convertability of the MFC films and coatings but there is also a significant risk of cracking of the thin and sensitive vacuum coating layer as the film or coating is remoisturized.

Thus, there remains a need for improved solutions to replace the combination of plastic films and aluminum foils in paper and paperboard based packaging materials, while maintaining acceptable liquid, water vapor, and oxygen barrier properties. At the same time, there is a need to replace the combination of plastic films and aluminum foils with alternatives that facilitate re-pulping and recycling of the used packaging materials.

### DESCRIPTION OF THE INVENTION

It is an object of the present disclosure to provide an alternative to the combination of plastic films and aluminum foils commonly used as barrier layers for providing water vapor barrier properties in packaging materials, such as liquid or food packaging board.

It is a further object of the present disclosure, to provide a barrier layer for a paper or paperboard based packaging laminate, such as a liquid or food packaging board, which provides good water vapor barrier properties even at higher relative humidity and temperature.

It is a further object of the present disclosure to provide a barrier layer, which has an oxygen transmission rate (OTR), measured according to the standard ASTM D-3985 at 50% relative humidity and 23° C., of less than 10 cc/m²/24 h.

It is a further object of the present disclosure to provide a barrier layer, which has a water vapor transmission rate (WVTR), measured according to the standard ASTM F1249 at 50% relative humidity and 23° C., of less than 10 g/m²/24 h.

It is a further object of the present disclosure to provide a barrier layer for a paper or paperboard based packaging laminate, such as a liquid or food packaging board, which barrier layer facilitates re-pulping of the packaging laminate as compared to packaging laminates using conventional combinations of plastic films and aluminum foils.

The above-mentioned objects, as well as other objects as will be realized by the skilled person in the light of the present disclosure, are achieved by the various aspects of the present disclosure.

The present invention is based on the understanding that very thin coating layers, typically having a thickness in the range of 20-600 nm, and more preferably in the range of 50-250 nm, formed by vacuum deposition processes, such as physical vapor deposition (PVD) or chemical vapor deposition (CVD), can when combined with a substrate formed of highly refined cellulose pulp (HRC) or microfibrillated cellulose (MFC) provide good oxygen and water vapor barrier properties, comparable to the barrier properties of thicker aluminum foils. As the thickness of the vacuum deposited coatings is typically at least an order of magnitude lower than the thickness of conventional foils, the metal content of the products can be dramatically reduced.

However, vacuum deposition coating performed directly on the substrate to be coated, so called direct vacuum coating, or direct metallization, has been found to be problematic for substrates formed of highly refined cellulose pulp (HRC) or microfibrillated cellulose (MFC). More specifically, degassing in connection with the vacuum treatment means that the substrate is dried to a very low moisture content. This drying and the subsequent remoisturizing to ambient moisture levels changes the mechanical properties of the HRC or MFC substrates. The drying will not only increase the cracking tendency and post-convertability of the substrates, but there is also significant risk of cracking of the thin and sensitive vacuum coating layer as the substrate is remoisturized.

The present invention is based on the realization that these problems can be overcome by replacing direct vacuum deposition coating of the substrate with a transfer coating technique, thus avoiding vacuum treatment of the barrier substrate.

According to a first aspect illustrated herein, there is provided a method for manufacturing a barrier layer for a paper or paperboard based packaging laminate, said method comprising:
a) providing a barrier substrate comprising at least 50 wt % highly refined cellulose pulp (HRC) based on dry weight of the barrier substrate, said HRC having a Schopper-Riegler (SR) number above 80 as determined by standard ISO 5267-1,
b) providing a transfer coating substrate comprising a vacuum coating layer and a backing layer separated by a release layer, and
c) transferring the vacuum coating layer from the backing layer to the barrier substrate by a transfer coating process using an adhesive layer applied on the barrier substrate and/or the vacuum coating layer to obtain a barrier layer for a paper or paperboard based packaging laminate.

Transfer coating of vacuum coating layers, also commonly referred to as transfer metallization when the coating comprises a metal, is a method conventionally used for preparing decorative layers on graphical paper substrates. The present inventors have found this coating technique, when combined with a substrate formed of highly refined cellulose pulp (HRC) or microfibrillated cellulose (MFC), can be used to form a highly useful oxygen and water vapor barrier layer suitable for paper or paperboard based packaging laminates. In addition to providing good oxygen and water vapor barrier properties, the inventive barrier layer may also form a good barrier for other gases, as well as aromas and odors.

Thus, the barrier substrate used in the inventive method comprises highly refined cellulose pulp. Refining, or beating, of cellulose pulps refers to mechanical treatment and modification of the cellulose fibers in order to provide them with desired properties. The highly refined cellulose fibers can be produced from different raw materials, for example softwood pulp or hardwood pulp. The highly refined cellulose fibers are preferably never dried cellulose fibers.

The barrier substrate comprises at least 50 wt % highly refined cellulose pulp (HRC) based on dry weight of the barrier substrate. In some embodiments, the barrier substrate comprises at least 70 wt %, preferably at least 90 wt %, highly refined cellulose pulp based on the dry weight of the barrier substrate.

The HRC has a Schopper-Riegler (SR) number above 80 as determined by standard ISO 5267-1. In some embodiments, the highly refined cellulose pulp has a Schopper-Riegler (SR) number above 85, preferably above 90, as determined by standard ISO 5267-1.

In some embodiments, the highly refined cellulose pulp is a microfibrillated cellulose (MFC).

Microfibrillated cellulose (MFC) shall in the context of the patent application mean a cellulose particle, fiber or fibril having a width or diameter of from 20 nm to 1000 nm.

Various methods exist to make MFC, such as single or multiple pass refining, pre-hydrolysis followed by refining or high shear disintegration or liberation of fibrils. One or several pre-treatment steps is usually required in order to make MFC manufacturing both energy efficient and sustainable. The cellulose fibers of the pulp used when producing MFC may thus be native or pre-treated enzymatically or chemically, for example to reduce the quantity of hemicellulose or lignin. The cellulose fibers may be chemically modified before fibrillation, wherein the cellulose molecules contain functional groups other (or more) than found in the original cellulose. Such groups include, among others, carboxymethyl (CM), aldehyde and/or carboxyl groups (cellulose obtained by N-oxyl mediated oxidation, for example “TEMPO”), or quaternary ammonium (cationic cellulose). After being modified or oxidized in one of the above-described methods, it is easier to disintegrate the fibers into MFC.

MFC can be produced from wood cellulose fibers, both from hardwood or softwood fibers. It can also be made from microbial sources, agricultural fibers such as wheat straw pulp, bamboo, bagasse, or other non-wood fiber sources. It can be made from pulp, including pulp from virgin fiber, e.g. mechanical, chemical and/or thermomechanical pulps. It can also be made from broke or recycled paper.

The barrier substrate is preferably formed from an aqueous suspension of the highly refined cellulose pulp which is then formed into a sheet or web and dewatered and/or dried. Forming, dewatering and drying of the barrier substrate can be done using methods known in the art, including but not limited to, casting on a solid surface followed by drying, forming on a paper or paperboard substrate followed by dewatering and drying, and forming on wire of a paper machine followed by dewatering and drying.

Depending on how the barrier substrate is prepared, the barrier substrate may be considered as a free-standing barrier substrate film or as a coating layer on a paper or paperboard substrate.

In some embodiments, the barrier substrate has a grammage in the range of 2-100 g/m², preferably in the range of 2-60 g/m², and more preferably in the range of 20-50 g/m².

In some embodiments, the barrier substrate is a free-standing barrier substrate film. The term film as used herein refers generally to a thin continuous sheet formed material. Depending on the composition of the barrier substrate film, the film can also be considered as a thin paper or even as a membrane. A free-standing barrier substrate should preferably have sufficient thickness, mechanical strength and rigidity in order for it to be handled, e.g. reeled, unreeled, coated, and/or laminated to a paper or paperboard substrate. A barrier substrate in the form of a free-standing barrier substrate film may typically have a grammage in the range of 20-100 g/m², preferably in the range of 20-60 g/m², and more preferably in the range of 20-50 g/m².

In some embodiments, the barrier substrate is instead a coating layer on a paper or paperboard substrate. When the barrier substrate is formed, or coated, on a paper or paperboard substrate followed by dewatering and drying, the resulting barrier substrate may be seen as a coating layer on the paper or paperboard substrate. A barrier substrate in the form of a coating layer on a paper or paperboard substrate can be made significantly thinner than a free-standing barrier substrate film, since mechanical strength and rigidity for handling can be provided by the paper or paperboard substrate. A barrier substrate in the form of a coating layer on a paper or paperboard substrate may typically have a grammage in the range of 2-20 g/m², preferably in the range of 2-15 g/m², and more preferably in the range of 2-10 g/m².

The barrier substrate is typically relatively dense. In some embodiments, the barrier substrate has a density above 800 kg/m³, preferably above 900 kg/m³. Unless otherwise stated, the density is determined according to the standard ISO 534.

In some embodiments, the barrier substrate has a Gurley Hill value above 5000 s/100 ml, preferably above 20 000 s/100 ml, and more preferably above 42 300 s/100 ml, as measured according to standard ISO 5636-5.

The inventive method is especially advantageous for substrates which are difficult or costly to dry completely. As the method does not involve subjecting the barrier substrate itself to a vacuum coating process, a relatively high remaining moisture content in the barrier substrate when the transfer coating process is performed can be accepted. Thus, in some embodiments, the barrier substrate, when subjected to the transfer coating process, has a moisture content 1.5 wt % or more, preferably 2 wt % or more, more preferably 3 wt % or more or 3.5 wt % or more or 4 wt % or more. The moisture content of the barrier substrate is preferably 15 wt % or less, 12 wt % or less, 10 wt % or less, or 9 wt % or less. In some embodiments the barrier substrate has a moisture content of 4 wt % or higher, such as in the range of 4-15 wt %, 4-12 wt %, 5-10 wt %, or 6-9 wt %. Unless otherwise stated, the moisture content is determined according to the standard ISO 638.

The barrier substrate comprising at least 50 wt % highly refined cellulose pulp (HRC) based on dry weight of the barrier substrate will typically have a relatively low resistance to water vapor. In some embodiments, the barrier substrate has a water vapor transmission rate (WVTR), measured according to the standard ASTM F1249 at 50% relative humidity and 23° C., of above 30 g/m²/24 h.

Onto the provided barrier substrate, a vacuum coating layer is applied by a transfer coating process to obtain a barrier layer for a paper or paperboard based packaging laminate. Transfer coating, also commonly referred to as transfer metallization when the coating comprises a metal, generally involves transferring a thin vacuum coating layer from a transfer coating substrate to a substrate to be coated, using an adhesive layer applied between the vacuum coating layer and the substrate to be coated.

The transfer coating substrate comprises a vacuum coating layer and a backing layer, and the vacuum coating layer and the backing layer are separated by a release layer having low adhesion to the vacuum coating layer and/or the backing layer, such that the vacuum coating layer can be readily separated from the backing layer.

For the transfer coating process, an adhesive layer is applied on the barrier substrate or on the vacuum coating layer or on both layers. The vacuum coating layer is transferred to the barrier substrate using the adhesive layer applied on the barrier substrate and/or the vacuum coating layer. The vacuum coating layer is contacted and adhered to the barrier substrate using the adhesive layer applied on the barrier substrate and/or the vacuum coating layer. Once the vacuum coating layer has adhered to the barrier substrate, the backing layer removed from the vacuum coating layer, leaving the adhered vacuum coating layer, and optionally the release layer, on the barrier substrate. Possible additional layers added between the release layer and the vacuum coating layer, and/or on top of the vacuum coating layer will also remain on the barrier substrate.

In some embodiments, the transfer coating process comprises
contacting and adhering the vacuum coating layer to the barrier substrate using the adhesive layer applied on the barrier substrate and/or the vacuum coating layer, and
removing the backing layer, leaving the vacuum coating layer, and optionally the release layer, on the barrier substrate.

The vacuum coating layer in contact with the barrier substrate via the adhesive layer may be subjected to various treatments for improving the adhesion between the vacuum coating layer and the barrier substrate. In some embodiments, the vacuum coating layer in contact with the barrier substrate via the adhesive layer is subjected to pressure, heat, and/or radiation to improve adhesion between the vacuum coating layer and the barrier substrate.

The temperature may vary depending on contact time and pressure but should generally be in the range of 40-250° C., and preferably in the range of 60-150° C.

The pressure should be high enough to obtain good transfer of the vacuum coating layer. In some embodiments, the pressure is in the range of 1-50 kg/cm. Pressure and heating may for example be provided in a heated nip or extended nip.

Transfer coating substrates similar to those for use in the present invention are known in the art, e.g. for preparing decorative layers on graphical paper substrates. However, as the purpose of the inventive method is to provide a barrier layer, the composition morphology and thickness of the vacuum coating layer may differ from those used for decorative purposes. The transfer coating substrate is typically prepared by coating a backing layer, preferably a polymer film, with a release layer. A vacuum coating layer is then deposited on the release layer. Optionally, additional intermediate layers may be added between the release layer and the vacuum coating layer, and/or top layers may be added on top of the vacuum coating layer. Additional layers may include protective layers for protecting the sensitive vacuum coating layer before the coating layer has been separated from the backing layer (protective top layer on top of the vacuum coating layer), or after the vacuum coating layer has been separated from the backing layer (protective intermediate layer between the release layer and the vacuum coating layer). Additional intermediate or top layers may also include barrier layers, e.g. gas or moisture barrier layers, or primer layers for improving the adhesion of the vacuum coating layer.

The backing layer primarily serves as a carrier for the release layer and the vacuum coating layer. The backing layer should preferably provide suitable mechanical and strength properties for the transfer coating process and a smooth and pinhole free surface for formation of the release layer and the vacuum coating layers. In some embodiments, the backing layer comprises a plastic film. The plastic film may for example be a polyethylene terephthalate (PET) film, but the skilled person understands that other polymer films may also be useful. After it has been removed from the vacuum coating layer during the transfer coating process, the backing layer may preferably be used again.

Release layers for transfer coating applications are well known in the art. Release layers may have many different chemical compositions with the common feature of having relatively weak adhesion to a substrate, such that the release layer can be easily removed or stripped from the substrate. Examples of common materials for use in the release layer include, but are not limited to, a film forming vinyl chloride-vinyl acetate copolymer or a film forming vinylidene chloride copolymer, or a combination thereof.

In some embodiments, the release layer comprises a layer of a material having lower adhesion to the backing layer or to the vacuum coating layer than the adhesion of the adhesive layer to the barrier substrate and to the vacuum coating layer. In this way, the vacuum coating, and possibly also the release layer, will remain on the adhesive layer when the backing layer is removed.

When the backing layer is removed the release layer may, depending on the adhesion characteristics of the release layer, either remain on the backing layer or on the vacuum coating layer. For achieving consistent production and performance, it is of course preferred that the release layer is not retained partially on the backing layer and partially on the vacuum coating layer when the backing layer is removed. The release layer is preferably selected such that the adhesion to either the backing layer or the vacuum coating layer is significantly stronger than the other, such that the entire release layer remains on one of the two surfaces as the backing layer is removed. In some embodiments, the release layer comprises a layer of a material having lower adhesion to the backing layer than to the vacuum coating layer, or having lower adhesion to the vacuum coating layer than to the backing layer, such that the entire release layer remains on the vacuum coating layer or on the backing layer when the backing layer is removed. It is typically preferred that the release layer remains on the vacuum coating layer when the backing layer is removed since the backing layer can then be conveniently coated again and reused. Thus, in some embodiments, the release layer is selected such that the adhesion between the vacuum coating layer and the release layer is significantly stronger than the adhesion between the release layer and the backing layer, such that the entire release layer remains on the surface of the vacuum coating layer as the backing layer is removed. The release layer on the surface of the vacuum coating layer will then act as a protective coating or varnish on the vacuum coating layer. Furthermore, the backing layer from which both the vacuum coating layer and the release layer has been removed during the transfer coating process may conveniently be used again in the preparation of a new transfer coating substrate. When an intermediate polymer layer is applied between the release layer and the vacuum coating layer, the intermediate polymer layer will remain on the surface of the vacuum coating layer as the backing layer is removed, and the intermediate polymer layer on the surface of the vacuum coating layer will also act as a protective coating on the vacuum coating layer. As an example, a carrier film, e.g. a PET film, is provided with a release layer (0.05-5 gsm), a protective coating 0.5-15 gsm, on top of the release layer, and then the thin vacuum coating layer on top of the protective coating. In some embodiments, the adhesive layer may also be provided on top of the vacuum coating layer. In addition to acting as an adhesive when the vacuum coating layer is transferred to the paper or paperboard substrate, the adhesive layer may also act as a protective coating for the vacuum coating layer during transport and handling.

The vacuum coating layer is formed on the release layer, or on an additional polymer layer applied on top of the release layer. Vacuum coating refers to a family of processes used to deposit layers of metals, metal oxides and other inorganic and organic compositions, typically atom-by-atom or molecule-by-molecule, on a solid surface. Multiple layers of the same or different materials can be combined. The process can be further specified based on the vapor source; physical vapor deposition (PVD) uses a liquid or solid source and chemical vapor deposition (CVD) uses a chemical vapor.

Vacuum coating typically results in very thin coatings. In some embodiments, the vacuum coating layer has a thickness in the range of 10-600 nm, preferably in the range of 10-250 nm, and more preferably in the range of 50-250 nm. This should be compared to conventional aluminum foils used in packaging laminates, which foils typically have thickness in the range of about 3-12 μm.

The vacuum coating layer may be inorganic or organic. In some embodiments, the vacuum coating layer comprises an inorganic vacuum coating layer, such as a metal, metal oxide, or ceramic vacuum coating layer.

In some embodiments, the vacuum coating layer comprises a metal or metal oxide selected from the group consisting of aluminum, magnesium, silicon, copper, aluminum oxides, magnesium oxides, silicon oxides, and combinations thereof, preferably aluminum or an aluminum oxide.

One preferred type of vacuum coating, often used for its barrier properties, in particular water vapour barrier properties, is an aluminum metal physical vapour deposition (PVD) coating. Such a coating, substantially consisting of aluminum metal, may typically have a thickness of from 50 to 250 nm, although a thickness even lower than 50 nm may also be useful, and even preferred in some embodiments. The thickness of the vacuum coating layer corresponds to less than 1% of the aluminum metal material typically present in an aluminum foil of conventional thickness for packaging, i.e. 6.3 μm. Thus, in some embodiments, the vacuum coating layer comprises aluminum.

The thickness of the vacuum coating layer may also be characterized by the optical density of the layer. In some embodiments the vacuum coating layer has an optical density above 1.8, preferably above 2.0, above 2.5, above 2.7, or above 3.0.

Aluminum oxide vacuum coating layers also known as AlOx coatings can provide similar barrier properties as aluminum metal coatings, but have the added advantage of thin AlOx coatings being transparent to visible light.

In some embodiments, the vacuum coating layer comprises an organic vacuum coating layer. The organic vacuum coating may for example be a vacuum coated carbon layer, such as a diamond-like carbon (DLC) layer formed from carbon or organic compounds.

The transfer coating substrate may further comprise a protective layer applied on top of the vacuum coating layer for protecting the thin and sensitive vacuum coating layer during manufacture, handling and transport prior to the transfer coating process. The protective layer applied on top of the vacuum coating layer may remain of the vacuum coating layer during the transfer coating process and form part of the obtained barrier layer. Alternatively, in some embodiments the protective layer applied on top of the vacuum coating layer may be removed before the transfer coating process.

During the transfer coating process, the vacuum coating layer is transferred from the backing layer to the barrier substrate using an adhesive layer applied on the barrier substrate and/or the vacuum coating layer to obtain a barrier layer for a paper or paperboard based packaging laminate. Many different types of adhesives and adhesive coating methods may be used with the invention.

Typically, the adhesive layer will comprise one or more adhesive polymers. The adhesive layer may be comprised entirely of the one or more adhesive polymers, or it may also further comprise other additives for facilitating the coating process or improving the properties of the adhesive layer.

In some embodiments, the adhesive layer comprises at least 50 wt % of an adhesive polymer or mixture of adhesive polymers based on dry weight.

In some embodiments, the adhesive layer comprises one or more adhesive polymers selected from the group consisting of polyolefins, polyurethanes, and acrylic copolymers.

In some embodiments, the adhesive layer comprises at least 50 wt % of a water-soluble polymer or mixture of water-soluble polymers based on dry weight. The water-soluble polymer of the adhesive layer is soluble in cold water or soluble in hot water, e.g. at a temperature below 100° C. or even above 100° C., for a given period of time. The water-soluble polymer in addition to acting as an adhesive for the vacuum coating layer, also facilitates separation of the vacuum coating layer and optional additional plastic layers applied on top of the adhesive layer or vacuum coating layer during repulping. In some embodiments, the water-soluble polymer is selected from the group consisting of a polyvinyl alcohol (PVOH), a carboxymethyl cellulose (CMC), a starch, an alginate, and a hemicellulose, preferably a PVOH.

The adhesive layer may be applied by any suitable method known in the art. The adhesive layer may for example be applied as a solution or dispersion in an aqueous or organic solvent carrier using liquid coating methods known in the art, in melt form using extrusion coating, or in the form of a solid film by lamination. In preferred embodiments, the adhesive layer is applied on the barrier substrate and/or the vacuum coating layer as a solution or dispersion in an aqueous carrier. Thus, in other words, the adhesive is preferably a water based adhesive.

Depending on the adhesive layer, the transfer coating process may be performed as a wet bond or dry bond lamination process. The transfer coating process may be performed with the adhesive layer in the form of a solution or dispersion in an aqueous or organic solvent carrier, such as in the case of liquid adhesive lamination, in melt form, such as in the case of extrusion coating lamination, or in the form of a solid film, such as in the case of adhesive film lamination. In some embodiments, the adhesive layer is applied on the barrier substrate and/or the vacuum coating layer as a solution or dispersion of an adhesive in an aqueous or organic solvent carrier and partially or fully dried on the barrier substrate and/or the vacuum coating layer before contacting and adhering the vacuum coating layer to the barrier substrate using the adhesive layer. A fully dried adhesive layer may be adhered to the barrier substrate by a dry bond lamination process using pressure, heat, and/or radiation.

The adhesive layer may be applied directly to the barrier substrate surface, or it may first be applied to the vacuum coating layer, and then applied to the barrier substrate together with the vacuum coating layer, or both. An advantage of applying the adhesive coating to both surfaces is that the wetting of the surfaces is reduced.

To minimize the risk of pinholes in the adhesive layer, the adhesive layer may preferably be applied in at least two different coating steps with drying of the coated film between the steps.

The adhesive layer is preferably formed by means of a liquid film coating process, i.e. in the form of a solution or dispersion which, on application, is spread out to a thin, uniform layer on the substrate and thereafter dried. The liquid phase of the solution or dispersion is preferably water or an aqueous solution, but organic solvents or mixtures of water or aqueous solutions and organic solvents may also be used. The one or more adhesive polymers may be present in the solution or dispersion in dissolved form or in the form of polymer particles, such as a latex. The adhesive layer can be applied by contact or non-contact coating methods. Examples of useful coating methods include, but are not limited to rod coating, curtain coating, film press coating, cast coating, transfer coating, size press coating, flexographic coating, gate roll coating, twin roll HSM coating, blade coating, such as short dwell time blade coating, jet applicator coating, spray coating, gravure coating or reverse gravure coating.

In some embodiments, at least one adhesive layer is applied in the form of a foam. Foam coating is advantageous as it allows for film forming at higher solids content and lower water content compared to a non-foamed coating. The lower water content of a foam coating also reduces the problems with rewetting of the barrier substrate. The foam may be formed using a polymeric or non-polymeric foaming agent. Examples of polymeric foaming agents include PVOH, hydrophobically modified starch, and hydrophobically modified ethyl hydroxyethyl cellulose.

In some embodiments, the adhesive layer further comprises a crosslinking agent capable of crosslinking the water-soluble polymer. The crosslinking agent may advantageously be applied together with the water-soluble polymer, and then activated, e.g. by heat or radiation, when the adhesive layer is in contact with the vacuum coating layer. Crosslinking improves the water vapor barrier properties of the adhesive layer. Suitable crosslinking agents include, but are not limited to polyfunctional organic acids or aldehydes, such as citric acid, glyoxal, and glutaraldehyde. In some embodiments, the crosslinking agent is an organic acid, and more preferably citric acid. The concentration of the crosslinking agent may for example be 1-20 wt %, preferably 1-15 wt %, based on the dry weight of the adhesive layer.

In some embodiments, the adhesive layer comprises PVOH and citric acid. Crosslinking of the PVOH with citric acid improves the water vapor barrier properties of the adhesive layer. Additionally, the crosslinking of the PVOH with citric acid in contact with the vacuum coating layer has been found to further improve adhesion of the vacuum coating layer and the overall water vapor barrier properties of the barrier layer.

In some embodiments, the adhesive layer comprises one or more additional polymer(s) in a total amount of 0-50 wt % based on dry weight. The additional polymer(s) may act to crosslink and/or further improve adhesion to the vacuum coating layer. Suitable additional polymer(s) include, but are not limited to polyvinyl pyrrolidone, polyvinyl amide, polyvinyl ethylene imine, polyacrylamide, cationic polyacrylamide, polyurethane, and derivatives thereof. Other suitable additional polymer(s) include latexes, such as styrene acrylate latex (SA latex), styrene butadiene latex (SB latex), polyvinyl acetate (PVAc), styrene butadiene acrylonitrile (SBN), polyvinylidene dichloride (PVDC), and hybrid-polymer emulsions such as grafted starch.

The basis weight of the adhesive layer may generally be in the range of 1-20 g/m². In some embodiments, the grammage of the adhesive layer is in the range of 2-15 g/m², more preferably in the range of 3-12 g/m².

In some embodiments, the adhesive layer further comprises up to 50 wt % of microfibrillated cellulose (MFC), nanocrystalline cellulose, a chemically modified cellulose derivative such as sodium carboxymethyl cellulose, hydroxypropyl cellulose, ethyl hydroxyethyl cellulose, cellulose acetate, hydroxyethyl cellulose, a hemicellulose, or a combination thereof, based on dry weight.

The vacuum coating layer is transferred from the backing layer to the barrier substrate by a transfer coating process using an adhesive layer applied on the barrier substrate and/or the vacuum coating layer.

In some embodiments, the adhesive layer is applied on the barrier substrate and/or the vacuum coating layer as a solution or dispersion of an adhesive in an aqueous or organic solvent carrier and partially or fully dried on the barrier substrate and/or the vacuum coating layer before contacting and adhering the vacuum coating layer to the barrier substrate using the adhesive layer. Partial drying generally means that the adhesive layer after drying has a total solid content below 90 wt %, preferably below 70 wt %, and more preferably below 50 wt %. Full drying generally means that the adhesive layer after drying has a total solid content above 90 wt %, preferably above 95 wt %, and more preferably above 98 wt %. Partial or full drying of the adhesive layer before contacting and adhering the vacuum coating layer to the barrier substrate reduces the risk of blister formation between the vacuum coating layer and the barrier substrate during or after the transfer coating process.

In some embodiments, the adhesive layer is applied to the vacuum coating layer as a solution or dispersion of an adhesive in an aqueous or organic solvent carrier and partially or fully dried on the vacuum coating layer before contacting and adhering the vacuum coating layer to the barrier substrate using the adhesive layer. Applying and partially or fully drying the solution or dispersion of adhesive specifically on the vacuum coating layer before contacting and adhering the vacuum coating layer to the barrier substrate is particularly advantageous, since in addition to reducing the risk of blister formation between the vacuum coating layer and the barrier substrate, it also allows for reduced wetting of the water sensitive barrier substrate during the transfer coating process. Embodiments, wherein the adhesive layer is applied to the vacuum coating layer and fully dried is further advantageous in that the dried adhesive layer acts as a protective layer for protecting the sensitive vacuum coating layer before the coating layer has been separated from the backing layer.

In some embodiments, the adhesive layer comprises a first adhesive layer and a second adhesive layer, wherein the first and second adhesive layers may comprise the same or different adhesives.

In some embodiments, the first adhesive layer is applied on the vacuum coating layer as a solution or dispersion of an adhesive in an aqueous or organic solvent carrier and partially or fully dried on the vacuum coating layer. The second adhesive layer is applied either on the first adhesive layer or on the barrier substrate, or both. Applying the second adhesive layer on the first adhesive layer is preferred as it allows for reduced wetting of the water sensitive barrier substrate.

The first and second adhesive layers may comprise the same or different adhesives. In some embodiments, the first and second adhesive layers comprise different adhesives. In some embodiments, the first adhesive layer is selected to provide good adhesion to the vacuum coating layer, and the second adhesive layer is selected to provide good adhesion to the barrier substrate and/or to provide other useful properties, such as barrier properties. In some embodiments, the first adhesive layer comprises at least 50 wt % of a polyurethane based on dry weight. A polyurethane in the first adhesive layer is advantageous as polyurethane provides good adhesion to the vacuum coating layer. In some embodiments, the second adhesive layer comprises at least 50 wt % of PVOH based on dry weight. PVOH in the second adhesive layer is advantageous as PVOH provides good adhesion to the barrier substrate, good gas barrier properties, and also facilitates separation of the vacuum coating layer and optional additional plastic layers applied on top of the adhesive layer or vacuum coating layer during repulping.

In a more specific embodiment, the vacuum coating layer comprises an aluminum or aluminum oxide vacuum coating layer, and the adhesive layer comprises at least 50 wt % of a polyurethane based on dry weight.

In another more specific embodiment, the vacuum coating layer comprises an aluminum or aluminum oxide vacuum coating layer, and the adhesive layer comprises at least 50 wt % of PVOH and 1-20 wt % of an organic acid, based on dry weight.

In another more specific embodiment, the vacuum coating layer comprises an aluminum or aluminum oxide vacuum coating layer, a first adhesive layer applied on the vacuum coating layer comprises at least 50 wt % of a polyurethane based on dry weight, and a second adhesive layer applied either on the first adhesive layer or on the barrier substrate, or both, comprises at least 50 wt % of PVOH based on dry weight. This particular configuration has been found to provide a particularly useful combination of good adhesion between the aluminum or aluminum oxide vacuum coated surface and the barrier substrate.

In some embodiments, the obtained barrier layer has an oxygen transmission rate (OTR), measured according to the standard ASTM D-3985 at 50% relative humidity and 23° C., of less than 10 cc/m²/24 h, preferably less than 5 cc/m²/24 h, and more preferably less than 1 cc/m²/24 h.

In some embodiments, the obtained barrier layer has a water vapor transmission rate (WVTR), measured according to the standard ASTM F1249 at 50% relative humidity and 23° C., of less than 10 g/m²/24 h, preferably less than 5 g/m²/24 h, and more preferably less than 1 g/m²/24 h.

In addition to providing good oxygen and water vapor barrier properties, the inventive barrier layer may also form a good barrier for other gases, as well as aromas and odors.

According to a second aspect illustrated herein, there is provided a method for manufacturing a paper or paperboard based packaging laminate, said method comprising:
i) providing a paper or paperboard substrate, and
ii) providing a barrier layer manufactured according to the method according to the first aspect on the paper or paperboard substrate to obtain the paper or paperboard based packaging laminate.

Paper generally refers to a material manufactured in thin sheets from the pulp of wood or other fibrous substances comprising cellulose fibers, used for writing, drawing, or printing on, or as packaging material.

Paperboard generally refers to strong, thick paper or cardboard comprising cellulose fibers used for boxes and other types of packaging. Paperboard can either be bleached or unbleached, coated or uncoated, and produced in a variety of thicknesses, depending on the end use requirements. Paperboard may be a single ply material, or a multiply material comprised of two or more plies. A common type of multiply paperboard is comprised of a lower density mid-ply (also sometimes referred to as “bulk ply”) sandwiched between two higher density outer plies. The lower density mid-ply may typically have a density below 750 kg/m³, preferably below 700, below 650, below 600, below 550, below 500, below 450, below 400 or below 350 kg/m³. The higher density outer plies typically have a density at least 100 kg/m³ higher than the mid-ply, preferably at least 200 kg/m³ higher than the mid-ply.

A paper or paperboard based packaging laminate is a packaging material formed mainly from paperboard. The paper or paperboard substrate can be made from pulp, including pulp from virgin fiber, e.g. mechanical, chemical and/or thermomechanical pulps. It can also be made from broke or recycled paper. In addition to the paper or paperboard, the paper or paperboard based packaging laminate may comprise additional layers or coatings designed to improve the performance and/or appearance of the packaging laminate.

The paper or paperboard based packaging laminate typically has a first outermost surface intended to serve as the outside surface, or print side, and a second outermost surface intended to serve as the inside surface of a packaging container. The side of the paper or paperboard substrate comprising the inventive barrier layer is preferably intended to serve as the inside surface of a packaging container.

In some embodiments, the paper or paperboard substrate has a grammage of at least 100 g/m². In some embodiments, the paper or paperboard substrate has a grammage of at least 150 g/m², 200 g/m², 250 g/m², 300 g/m², 350 g/m², or 400 g/m². The grammage of the paper or paperboard substrate is preferably below 1000 g/m², 800 g/m², or 600 g/m². Unless otherwise stated, the grammage is determined according to the standard ISO 536.

In some embodiments, the paper or paperboard substrate has a density below 700 kg/m³, preferably below 600 kg/m³. Unless otherwise stated, the density is determined according to the standard ISO 534.

The paper or paperboard substrate may be a single ply paperboard or a multiply paperboard. In some embodiments, the paper or paperboard substrate is a multiply paperboard. In some embodiments the paper or paperboard substrate is a multiply paperboard comprised of two or more plies. In some embodiments the paper or paperboard substrate is a multiply paperboard comprised of three or more plies. In some embodiments the paper or paperboard substrate is a multiply paperboard comprised of a lower density mid-ply sandwiched between two higher density outer plies.

In some embodiments, the paper or paperboard substrate is a foam formed paperboard. In some embodiments wherein the paper or paperboard substrate is a multiply paperboard, at least one of the plies, preferably a mid-ply, is foam formed.

The structure of the inventive paper or paperboard based packaging laminate enables the use of a larger amount of recycled fibers in the paper or paperboard substrate since the barrier structure hinders the migration of mineral oil based compounds. Thus, in some embodiments, the paper or paperboard substrate comprises at least 5 wt % recycled fibers, preferably at least 10 wt % recycled fibers.

In some embodiments, the paper or paperboard substrate further comprises a mineral coating layer on one or both of its main surfaces. In some embodiments, the mineral coating layer comprises
50-95 wt % of a particulate mineral, and
5-50 wt % of a binder,
   based on the total dry weight of the mineral coating layer.

In some embodiments, the mineral coating layer comprises 10-35 wt % binder.

In some embodiments, the particulate mineral is selected from the group consisting of kaolin, calcium carbonate, bentonite, talc, and combinations thereof, preferably kaolin or calcium carbonate, and more preferably kaolin.

The binder may comprise a single binder or a combination of binders. The binder may preferably comprise a water-dispersible or water-soluble binder, or a combination thereof. In some embodiments, the water-dispersible binder comprises a latex binder. In some embodiments, the water-soluble binder comprises a starch, PVOH, a cellulose derivate such as CMC, a protein, or seaweed. An advantage of using a water-soluble binder is that the laminate will be even more easy to recycle.

In some embodiments, the grammage of the mineral coating layer is in the range of 4-30 g/m², more preferably in the range of 6-14 g/m².

The mineral coating layer may preferably be applied in at least two different coating steps with drying of the coated film between the steps. The mineral coating layer may also be calendered, preferably in a soft calender or belt calender.

The provision of the inventive barrier layer on the paper or paperboard substrate can be achieved in a number of different ways.

In some embodiments, the provision in step ii) comprises laminating a free-standing barrier layer manufactured according to the first aspect to the paper or paperboard substrate.

In some embodiments, the provision in step ii) comprises laminating a barrier substrate comprising at least 50 wt % highly refined cellulose pulp (HRC) based on dry weight of the barrier substrate to the paper or paperboard substrate and then transferring the vacuum coating layer from the backing layer of the transfer coating substrate to the barrier substrate according to the first aspect.

Lamination of the barrier layer or barrier substrate to the paper or paperboard substrate can be achieved using an adhesive tie layer applied between the barrier layer or barrier substrate and the paper or paperboard substrate. The tie layer may be an adhesive layer applied by any suitable method known in the art. The tie layer may for example be an adhesive layer applied as a solution or dispersion of an adhesive in an aqueous or organic solvent carrier using liquid coating methods known in the art, or an adhesive applied in melt form using extrusion coating, or in the form of a solid adhesive film by lamination.

In some embodiments, the provision in step ii) comprises coating the paper or paperboard substrate with a coating dispersion comprising at least 50 wt % highly refined cellulose pulp (HRC) based on dry weight of the coating dispersion and drying the coating dispersion to form a barrier substrate on the paper or paperboard substrate, and then transferring the vacuum coating layer from the backing layer to the barrier substrate according to the first aspect.

According to a third aspect illustrated herein, there is provided a barrier layer obtained by a method according to the first aspect.

According to a fourth aspect illustrated herein, there is provided a paper or paperboard based packaging laminate obtained by a method according to the second aspect.

The inventive paper or paperboard based packaging laminate can provide an alternative to conventional materials using aluminum foil layers, which can more readily be repulped and recycled. In some embodiments, the paper or paperboard based packaging laminate has a reject rate according to PTS RH 021/97 of less than 30%, preferably less than 20%, more preferably less than 10%.

The paper or paperboard based packaging laminate may further be provided with an outermost polymer layer on one side or on both sides. The outermost polymer layers preferably provide liquid barrier properties and mechanical protection for the paper or paperboard based packaging laminate surface. The outermost polymer layer is preferably also heat-sealable.

In some embodiments, the paper or paperboard based packaging laminate comprises a first outermost polymer layer, preferably a polyethylene layer, arranged on the paper or paperboard substrate.

In some embodiments, the paper or paperboard based packaging laminate further comprises a second outermost polymer layer, preferably a polyethylene layer, arranged on the vacuum coating layer.

The outermost polymer layers may of course interfere with repulpability but may still be required or desired in some applications. The additional polymer layers may for example be applied by extrusion coating, film lamination or dispersion coating.

The outermost polymer layers may comprise any of the thermoplastic polymers commonly used in protective and/or heat-sealable layers in paper or paperboard based packaging laminates in general or polymers used in liquid or food packaging board in particular. Examples include polyethylene (PE), polyethylene terephthalate (PET), polyethylene furanoate (PEF), polypropylene (PP), polyhydroxyalkanoates (PHA), polylactic acid (PLA), polyglycolic acid (PGA), starch and cellulose. Polyethylenes, especially low density polyethylene (LDPE) and high density polyethylene (HDPE), are the most common and versatile polymers used in liquid or food packaging board. The polymers used are preferably manufactured from renewable materials.

Thermoplastic polymers are useful since they can be conveniently processed by extrusion coating techniques to form very thin and homogenous films with good liquid barrier properties. In some embodiments, the additional polymer layer comprises polypropylene or polyethylene. In preferred embodiments, the outermost polymer layers comprise polyethylene, more preferably LDPE or HDPE.

In some embodiments, the outermost polymer layers are formed by extrusion coating of the polymer onto a surface of the paper or paperboard substrate or laminate. Extrusion coating is a process by which a molten plastic material is applied to a substrate to form a very thin, smooth and uniform layer. The coating can be formed by the extruded plastic itself, or the molten plastic can be used as an adhesive to laminate a solid plastic film onto the substrate. Common plastic resins used in extrusion coating include polyethylene (PE), polypropylene (PP), and polyethylene terephthalate (PET).

The basis weight of each of the outermost polymer layers is preferably less than 50 g/m². In order to achieve a continuous and substantially defect free film, a basis weight of the outermost polymer layer of at least 8 g/m², preferably at least 12 g/m² is typically required. In some embodiments, the basis weight of the outermost polymer layer is in the range of 8-50 g/m², preferably in the range of 12-50 g/m².

Some examples of possible arrangements of the inventive barrier layer in a paper or paperboard based packaging laminate are shown below:
polyolefin/paperboard substrate/tie layer/barrier layer/polyolefin
paperboard substrate/tie layer/adhesive layer/barrier layer/polyolefin
polyolefin/paperboard substrate/mineral coating/tie layer/barrier layer/polyolefin
paperboard substrate/tie layer/barrier layer/polyolefin
paperboard substrate/tie layer/barrier layer/primer coating layer/polyolefin
ink receiving layer/paperboard/tie layer/barrier layer/polyolefin

Generally, while the products, polymers, materials, layers and processes are described in terms of “comprising” various components or steps, the products, polymers, materials, layers and processes can also “consist essentially of” or “consist of” the various components and steps.

While the invention has been described with reference to various exemplary embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

### EXAMPLES

### Example 1 (Comparative)—Direct Vacuum Coating of Packaging Paper

A one side mineral coated packaging paper substrate with a grammage of 80 g/m² was used. The physical properties of the paper substrate were: grammage (ISO 536) 80 g/m², thickness (ISO 534) 80 μm, tensile strength (ISO 1924-2 (MD)) 4.3 kN/m, tearing strength (ISO 1974 (CD)) 650 mN, moisture content (ISO 638) 4.0%, Cobb60 (ISO 535, reverse) 25 g/m², and opacity (ISO 2471 (C/2°) 96%.

The barrier properties (OTR measured according to the standard ASTM D-3985 at 50% relative humidity and 23° C. and WVTR measured according to the standard ASTM F1249 at 50% relative humidity and 23° C.) of the paper substrate before vacuum coating were out of range (no barrier properties). The paper substrate was prime coated with a PVOH based solution in three thin layers to give a total coat weight of 4 g/m². After coating, the paper substrate was subjected to vacuum coating with Al₂O₃ to obtain a coat weight corresponding to an optical density of 3.5. After the vacuum coating, the barrier properties (OTR and WVTR) were measured again. The OTR (23/50) was 512 cc/m²/24 h and the WVTR (23/50) was 0.19 g/m²/24 h.

### Example 2—Transfer Coating on Packaging Paper Substrate

In this case, a one side mineral coated packaging paper substrate having a grammage of 90 g/m² was used and transfer coating was performed on the mineral coated side. The physical properties of the packaging paper substrate were: thickness (ISO 534): 90 μm, tensile strength (ISO 1924-2 (MD)) 4.6 kN/m, tearing strength (ISO 1974 (CD)) 780 mN, moisture content (ISO 638) 4.0%, Cobb60 (ISO 535, reverse) 25 g/m², and opacity (ISO 2471 (C/2°) 97%.

For the transfer coating, a transfer coating substrate vas prepared by vacuum depositing a layer of AlOx onto a release layer coated on a PET film backing layer. A water based polyurethane adhesive was applied onto the vacuum deposited layer and dried. The adhesive-AlOx layer was then transferred to the surface of the paper substrate using dry lamination under elevated temperature and pressure. The backing layer was stripped off 24 h after the lamination.

The WVTR (ASTM F1249, 23/50) of the packaging paper substrate before transfer coating was out of range (no WVTR barrier). After transfer coating the WVTR (ASTM F1249, 23/50) was 0.3 g/m²/24 h.

### Example 3—Transfer Coating on Barrier Substrate Comprising Highly Refined Pulp

A highly refined pulp comprising 100% of pulp having a Schopper-Riegler value of about 95 as determined by standard ISO 5267-1 was prepared into a thin 32 g/m² barrier substrate on a pilot paper machine.

The barrier substrate was then subjected to transfer coating as described in Example 2.

After the transfer coating, the barrier properties (OTR and WVTR) were measured. The OTR (ASTM D-3985, 23/50) was 2.5 cc/m²/24 h and the WVTR (ASTM F1249, 23/50) was 1.7 g/m²/24 h, confirming that both low OTR and WVTR can be obtained after transfer coating of a barrier substrate comprising highly refined pulp.

### Example 4—Transfer Coating on PVOH Coated Barrier Substrate Comprising Highly Refined Pulp

A highly refined pulp comprising about 80% of pulp with SR about 95 as determined by standard ISO 5267-1 and 20% of kraft pulp was prepared into a thin 32 g/m² barrier substrate on a pilot paper machine. The OTR (ASTM D-3985, 23/50) of the uncoated substrate was >366 cc/m²/24 h and the WVTR (ASTM F1249, 23/50) was >38 g/m²/24 h.

The barrier substrate was prime coated with a PVOH based solution to give a total coat weight of ca 2-4 g/m².

The barrier substrate was then subjected to transfer coating as described in Example 2.

After the transfer coating, the barrier properties (OTR and WVTR) were measured. The OTR (ASTM D-3985, 23/50) was 0.3 cc/m²/24 h and the WVTR (ASTM F1249, 23/50) was 0.6 g/m²/24 h, confirming that both low OTR and WVTR can be obtained after transfer coating of a barrier substrate comprising highly refined pulp.

### Example 5—Transfer Metallization on Barrier Substrate Comprising Fine MFC

A fine MFC suspension was prepared by fibrillating enzyme treated kraft pulp and the MFC suspension was then cast formed into a barrier substrate having a grammage of 30 g/m². The OTR (ASTM D-3985, 23/50) of the uncoated barrier substrate was 4.5 cc/m²/24 h and the WVTR (ASTM F1249, 23/50) was 46 g/m²/24 h.

The barrier substrate was then subjected to transfer coating as described in Example 2.

After the transfer coating, the barrier properties (OTR and WVTR) were measured. The OTR (ASTM D-3985, 23/50) was 0.4 cc/m²/24 h and the WVTR (ASTM F1249, 23/50) was 0.4 g/m²/24 h, confirming that both low OTR and WVTR can be obtained after transfer coating of a barrier substrate comprising fine MFC.

1. A method for manufacturing a barrier layer for a paper or paperboard based packaging laminate, said method comprising:
a) providing a barrier substrate comprising at least 50 wt % highly refined cellulose pulp (HRC) based on a dry weight of the barrier substrate, said HRC having a Schopper-Riegler (SR) number above 80 as determined by standard ISO 5267-1,
b) providing a transfer coating substrate comprising a vacuum coating layer and a backing layer separated by a release layer, and
c) transferring the vacuum coating layer from the backing layer to the barrier substrate by a transfer coating process using an adhesive layer applied on the barrier substrate, or the vacuum coating layer, or both to obtain a barrier layer for a paper or paperboard based packaging laminate.

2. The method according to claim 1, wherein the barrier substrate is a free-standing barrier substrate film.

3. The method according to claim 1, wherein the barrier substrate is a coating layer on a paper or paperboard substrate.

4. The method according to claim 1, wherein the barrier substrate has a grammage in a range of 2-100 g/m².

5. The method according to claim 1, wherein the barrier substrate comprises at least 70 wt % highly refined cellulose pulp based on the dry weight of the barrier substrate.

6. The method according to claim 1, wherein the highly refined cellulose pulp has a Schopper-Riegler (SR) number above 85, as determined by standard ISO 5267-1.

7. The method according to claim 1, wherein the highly refined cellulose pulp comprises a microfibrillated cellulose (MFC).

8. The method according to claim 1, wherein the barrier substrate has a Gurley Hill value above 5000 s/100 ml, as measured according to standard ISO 5636-5.

9. The method according to claim 1, wherein the barrier substrate has a moisture content of 1.5 wt % or more, as determined according to ISO 638.

10. The method according to claim 1, wherein the barrier substrate has a water vapor transmission rate (WVTR), measured according to standard ASTM F1249 at 50% relative humidity and 23° C., of above 30 g/m²/24 h.

11. The method according to claim 1, wherein the transfer coating process comprises
contacting and adhering the vacuum coating layer to the barrier substrate using the adhesive layer applied on the barrier substrate and/or the vacuum coating layer, and
removing the backing layer, leaving the vacuum coating layer, and optionally the release layer, on the barrier substrate.

12. (canceled)

13. (canceled)

14. (canceled)

15. (canceled)

16. The method according to claim 1, wherein the vacuum coating layer comprises an inorganic vacuum coating layer.

17. The method according to claim 1, wherein the vacuum coating layer comprises an organic vacuum coating layer.

18. The method according to claim 1, wherein the vacuum coating layer has a thickness in a range of 10-600 nm.

19. (canceled)

20. (canceled)

21. The method according to claim 1, wherein the adhesive layer comprises at least 50 wt % of a water-soluble polymer or mixture of water-soluble polymers based on a dry weight.

22. The method according claim 21, wherein the water-soluble polymer is selected from a group consisting of: a polyvinyl alcohol (PVOH), a carboxymethyl cellulose (CMC), a starch, an alginate, and a hemicellulose.

23. The method according to claim 21, wherein the adhesive layer further comprises a crosslinking agent configured to crosslink the water-soluble polymer.

24. The method according to claim 21, wherein the adhesive layer further comprises up to 50 wt % of microfibrillated cellulose (MFC), nanocrystalline cellulose, a chemically modified cellulose derivative such as sodium carboxymethyl cellulose, hydroxypropyl cellulose, ethyl hydroxyethyl cellulose, cellulose acetate, hydroxyethyl cellulose, a hemicellulose, or a combination thereof, based on the dry weight.

25. The method according to claim 1, wherein the barrier layer has an oxygen transmission rate (OTR), measured according to standard ASTM D-3985 at 50% relative humidity and 23° C., of less than 10 cc/m²/24 h.

26. The method according to claim 1, wherein the barrier layer has a water vapor transmission rate (WVTR), measured according to standard ASTM F1249 at 50% relative humidity and 23° C., of less than 10 g/m²/24 h.

27. A method for manufacturing a paper or paperboard based packaging laminate, said method comprising:
i) providing a paper or paperboard substrate, and
ii) providing the barrier layer manufactured according to the method of claim 1.

28. The method according to claim 27, wherein step ii) comprises laminating a free-standing barrier layer.

29. The method according to claim 27, wherein step ii) comprises laminating the barrier substrate to the paper or paperboard substrate and then transferring the vacuum coating layer from the backing layer to the barrier substrate.

30. The method according to claim 27, wherein step ii) comprises coating the paper or paperboard substrate with a coating dispersion comprising at least 50 wt % highly refined cellulose pulp (HRC) based on a dry weight of the coating dispersion and drying the coating dispersion to form the barrier substrate, and then transferring the vacuum coating layer from the backing layer to the barrier substrate.

31. (canceled)

32. (canceled)
